(19) United States
(12) Patent Application Publication
(10) Pub. No.: US 2010/0258915 A1
(43) Pub. Date: Oct. 14, 2010

(54) SEMICONDUCTOR DEVICE AND METHOD OF MANUFACTURING THE SAME

(75) Inventor: KAZUKI HISAKANE, TOKYO (JP)

Correspondence Address: YOUNG & THOMPSON, 209 Madison Street, Suite 500, Alexandria, VA, 22314, US

(73) Assignee: ELPIDA MEMORY, INC, TOKYO (JP)

(21) Appl. No.: 12/757,151

(22) Filed: Apr. 9, 2010

(30) Foreign Application Priority Data
Apr. 13, 2009 (JP) 2009-097035

(51) Int. Cl. H01L 29/06; H01L 21/20; H01L 21/322; H01L 21/50

(52) U.S. Cl. 257/618; 438/478; 438/476; 438/107; 257/E21.09; 257/E21.318; 257/E21.499; 257/E29.001

(57) ABSTRACT

A method of manufacturing a semiconductor device may include, but is not limited to the following processes. An epitaxial layer is formed on a semiconductor substrate. A semiconductor element is formed in the epitaxial layer. The semiconductor substrate is removed from the epitaxial layer.

### BACKGROUND OF THE INVENTION

1. Field of the Invention

The present invention relates to a semiconductor device and a method of manufacturing the same.

Priority is claimed on Japanese Patent Application No. 2009-097035, filed Apr. 13, 2009, the content of which is incorporated herein by reference.

2. Description of the Related Art

Recently, gettering, such as IG (Intrinsic Gettering) or EG (Extrinsic Gettering), has been used in semiconductor-device manufacturing processes in order to prevent degradation of characteristics of a semiconductor device due to mobile ions in heavy metals.

Generally, a wafer used for manufacturing recent miniaturized semiconductor elements is polished on both surfaces thereof. Therefore, heavy metal trapping by an IG method using oxygen precipitation in a mono-crystalline silicon substrate is effective.

Additionally, to solve a problem of heavy metal contamination in a post-process (package assembly process) of semiconductor-element manufacturing processes, Japanese Patent Laid-Open Publication Nos. 2005-317805 and 2005-317735 disclose a semiconductor device achieving an IG effect even in the assembly process.

With miniaturization of electronic devices, the demand for further miniaturization of semiconductor devices is increasing. The above related arts disclose a technique of preventing, by a gettering method, a degradation of characteristics of semiconductor elements formed on a semiconductor substrate when the semiconductor substrate is polished to be thinner and then assembled into a predetermined package.

However, the inventor of the present invention found that the gettering method in the assembly process causes the following problems.

If heavy metal contamination affects semiconductor elements, leak current is increased at a PN junction forming a source-and/or-drain electrode of a MOS transistor. For this reason, DRAM (Dynamic Random Access Memory) elements, which are easily affected by leak current, are used to measure a change in the number of defective bits caused by loss of stored electric charge due to the leak current. Thus, the effect of the contamination can be evaluated.

The inventor of the present invention evaluated the effect of heavy metal contamination by forming DRAM elements on a semiconductor substrate including a gettering layer and by assembling the DRAM elements and the semiconductor substrate to a package. Regarding the assembly, the gettering layer remained in the semiconductor substrate even after the rear surface of the semiconductor substrate was polished until the semiconductor substrate had a predetermined thickness.

The degrees of heavy metal contamination after the rear surface of the semiconductor substrate was polished were categorized into multiple stages. Then, the number of defective bits stored in the DRAM elements after the assembly was measured. As a result, the number of defective bits stored in the DRAM elements increased even after cleanliness was increased to reduce the effect of the metal contamination as much as possible.

The reason of the above result is explained here with reference to FIG. 6. FIG. 6 is a cross-sectional view illustrating a semiconductor device 50. Elements 53, such as a MOS transistor, are formed on a main surface of the semiconductor substrate 51. A gettering layer 52 is formed on a rear surface of the semiconductor substrate 51. A thickness D of the semiconductor substrate 51 with the gettering layer 52 is adjusted to a predetermined size.

A thermal treatment is carried out at 150° C. to 300° C. in the package assembly process, which is after the semiconductor substrate is polished on the rear surface thereof so as to be thinner. Various heavy metals 54a are trapped in the gettering layer 52 in the pre-process (diffusion process) of semiconductor-device manufacturing processes.

If heat required for the assembly is added, some of the trapped heavy metals 54a are released and diffused toward the main surface of the semiconductor substrate 51, as heavy metals 54b. The released heavy metals 54b affect the elements 53, causing an increase in leak current at the PN junction, or causing an increase in the number of defective bits in the case of the DRAM elements.

In other words, the semiconductor substrate including the gettering layer is effective as a trap layer for trapping heavy metals newly attached thereto upon the polishing of the rear surface, but causing the heavy metals to release upon the assembly. For this reason, the release of heavy metals dominates the trapping of heavy metals in a case where cleanliness in a process after the polishing of the rear surface is enhanced to prevent the effect of newly attached heavy metals, thereby causing a decrease in the manufacturing yield.

### SUMMARY

In one embodiment, a method of manufacturing a semiconductor device may include, but is not limited to the following processes. An epitaxial layer is formed on a semiconductor substrate. A semiconductor element is formed in the epitaxial layer. The semiconductor substrate is removed from the epitaxial layer.

In another embodiment, a semiconductor device may include, but is not limited to a first semiconductor substrate comprising a semiconductor element. The first semiconductor substrate is free of a gettering layer.

In still another embodiment, a method of manufacturing a semiconductor device may include, but is not limited to the following processes. A semiconductor substrate is formed. The semiconductor substrate comprises a semiconductor base substrate and an epitaxial layer on the semiconductor base substrate. The semiconductor base substrate comprises a gettering layer. A semiconductor element is formed in the epitaxial layer. The gettering layer traps heavy metal diffusing from the semiconductor substrate toward the epitaxial layer. The semiconductor base substrate is removed from the epitaxial layer. The gettering layer is removed with the semiconductor base substrate.

### BRIEF DESCRIPTION OF THE DRAWINGS

The above features and advantages of the present invention will be more apparent from the following description of certain preferred embodiments taken in conjunction with the accompanying drawings, in which:

FIGS. 1 to 3 are cross-sectional views illustrating a method of manufacturing a semiconductor device according to a first embodiment of the present invention;

FIG. 4 is a cross-sectional view illustrating an example of the semiconductor device according to the first embodiment;

FIG. 5 is a cross-sectional view illustrating another example of the semiconductor device according to the first embodiment; and

FIG. 6 illustrates behavior of heavy metal molecules included in a semiconductor device according to a related art.

### DETAILED DESCRIPTION OF THE PREFERRED EMBODIMENTS

The present invention will now be described herein with reference to illustrative embodiments. The accompanying drawings explain a semiconductor device and a method of manufacturing the same in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

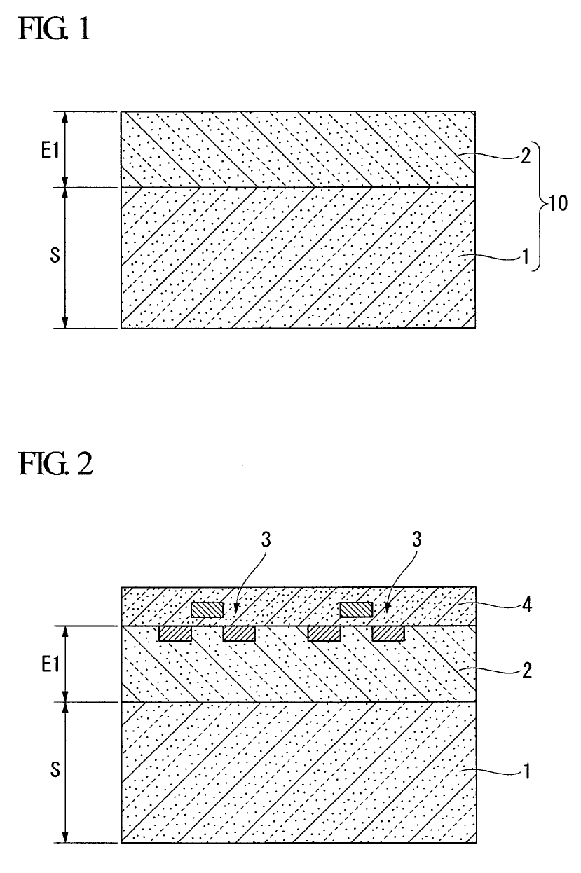

Hereinafter, a method of manufacturing a semiconductor device according to a first embodiment of the present invention is explained with reference to FIGS. 1 to 3. FIGS. 1 to 3 are cross-sectional views illustrating a method of manufacturing a semiconductor device according to the first embodiment.

The method includes a film formation process, an element formation process, and a removal process. In the film formation process, an epitaxial layer is formed on a semiconductor substrate by epitaxial growth. In the element formation process, semiconductor elements are formed in the epitaxial layer. In the removal process, the semiconductor substrate is removed while only the epitaxial layer is remained. Hereinafter, each process is specifically explained.

In the film formation process, a semiconductor substrate 1 made of monocrystalline silicon is formed by a CZ (Czochralski) process or the like. The semiconductor substrate 1 is used for a base substrate. Then, an epitaxial layer 2 made of monocrystalline silicon is epitaxially grown from the semiconductor substrate 1, as shown in FIG. 1. Thus, the semiconductor substrate 1 and the epitaxial layer 2 form an epitaxial semiconductor substrate 10.

A thickness S of the semiconductor substrate 1 can be adjusted according to a diameter of the epitaxial semiconductor substrate 10 in consideration of strength required for the manufacturing process. For example, when the diameter of the semiconductor substrate 1 is 300 mm, the thickness S of the semiconductor substrate 1 is preferably set to be approximately 750 μm.

The epitaxial layer 2 is formed by CVD (Chemical Vapor Deposition) at a temperature of 1100° C. in a hydrogen atmosphere. Preferably, a thickness E1 of the epitaxial layer 2 is in the range of 10 to 100 μm. Although the thickness E1 of the epitaxial layer 2 can be greater than 100 μm, an effect of trapping heavy metals diffusing from a main surface side in a pre-process of the semiconductor-device manufacturing processes degrades.

For this reason, the thickness E1 of the epitaxial layer 2 is preferably approximately 100 μm at most. A lower limit of the thickness E1 of the epitaxial layer 2 is preferably 10 μm or more. The pre-process includes the film formation process and the element formation process.

When the monocrystalline silicon layer is formed, a p-type or n-type impurity can be implanted into the semiconductor substrate 1 and the epitaxial layer 2 according to characteristics of semiconductor elements to be formed.

Generally, the semiconductor (silicon) substrate 1 formed by the CZ process includes many oxygen impurities that will be oxygen precipitate, i.e., BMD (Bulk Micro Defect) causing a defect, a dislocation, or the like. The oxygen precipitate included in the semiconductor substrate 1 serves as a gettering layer in the pre-process.

On the other hand, since the epitaxial growth is carried out in the hydrogen atmosphere at a temperature of 1100° C. or more to form the epitaxial layer 2, an oxygen-precipitate-based gettering layer is not formed in the epitaxial layer 2.

In other words, only the semiconductor substrate 1 of the epitaxial semiconductor substrate 10 includes the gettering layer. On the other hand, the epitaxial layer 2 of the epitaxial semiconductor substrate 10 does not include the gettering layer.

The gettering layer is used for trapping heavy metals therein by EG or IG. The gettering layer may be formed by oxygen precipitation in crystalline silicon formed by CZ or by physically damaging a rear surface of the semiconductor substrate 1.

Then, in the element formation process, a multi-layered structure including an oxide film, a wiring layer, or the like is formed on a surface of the epitaxial layer 2. Thus, semiconductor elements 3, such as a MOS transistor and a capacitor, are formed as shown in FIG. 2.

Then, a protection film 4 made of silicon oxide (SiO₂) or silicon oxynitride (SiON) is formed so as to cover the semiconductor elements 3. The protection film 4 serves as an insulating film and prevents heavy metals from newly diffusing toward the epitaxial layer 2 through the protection film 4.

Although the type of semiconductor element is not limited, the present invention has a striking effect on elements, such as DRAM, CCD, and a CMOS sensor, which are susceptible to the effect of leak current due to heavy-metal contamination.

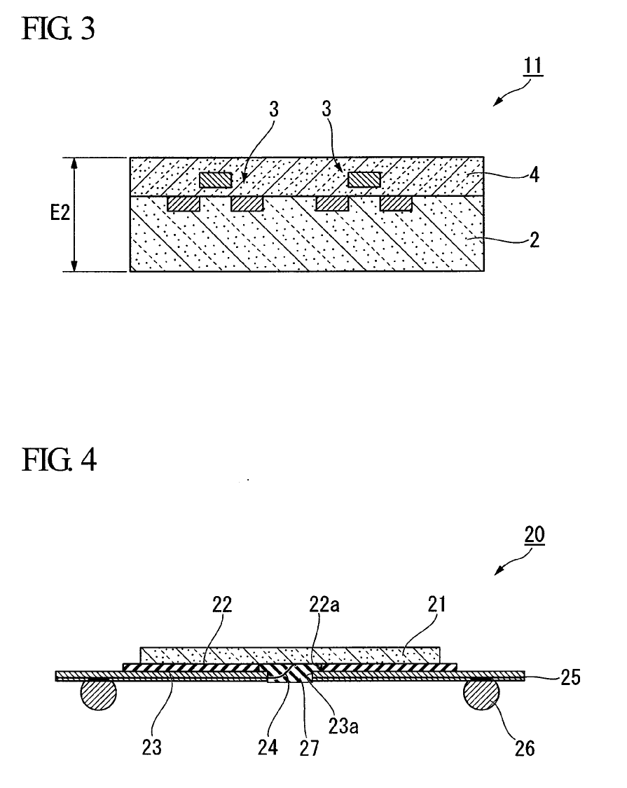

Then, in the removal process, the semiconductor substrate 1 is ground from the rear surface thereof. In this case, the entire semiconductor substrate 1 is removed so as to have only the epitaxial layer 2 remain, as shown in FIG. 3. Thus, a semiconductor device 11, which includes the semiconductor elements 3 in the epitaxial layer 2 without a gettering layer, can be obtained.

In the removal process, not only the semiconductor substrate 1 is removed, but also the epitaxial layer 2 can be polished after the grinding process so that the semiconductor device 11 has a desired thickness E2. The thickness E2 of the semiconductor device 11 after the semiconductor substrate 1 is removed is preferably 10 μm to 100 μm, which is required for a package as will be explained later. For this reason, the thickness E1 of the epitaxial layer 2 (shown in FIG. 2) is preferably set to be optimal before the removal process in consideration of the thickness E2 of the semiconductor device 11.

If the semiconductor device 11 is polished to be thinner, the strength thereof degrades, and therefore the semiconductor device 11 easily cracks. For this reason, preferably, the rear surface of the semiconductor device 11 (i.e., the rear surface of the epitaxial layer 2) is mechanically polished by a diamond grindstone or the like, and then mirror polishing (micro surface polishing) is carried out.

Since the semiconductor device 11 has no gettering function after the removal process, heavy metals have to be prevented from being newly attached until the next process.

After the film formation process, the element formation process, and the removal process (i.e., the pre-process), the following assembly process (i.e., a post-process) is carried out to form a packaged semiconductor device.

Hereinafter, the assembly process is explained with reference to FIG. 4. FIG. 4 is a cross-sectional view illustrating a BGA (Ball Grid Array) package 20, which is an example of a semiconductor device. The package 20 includes a semiconductor chip 21.

The semiconductor chip 21 is fixed to a support substrate 23 through an adhesive layer 22 including elastomer. The support substrate 23 has a hole 23a. The adhesive layer 22 has a hole 22a corresponding to the hole 23a. A protection resin seal 27 fills the holes 22a and 23a.

The support substrate 23 includes a wiring layer 25. Bonding pads (not shown) on the wiring layer 25 is connected to bonding pads (not shown) on the semiconductor chip 21 through a lead 24. Multiple solder balls 26 are provided on the support substrate 23. The solder balls 26 are electrically connected to the semiconductor chip 21 through the wiring layer 25.

Since the semiconductor device 11 has no gettering function after the removal process, the following process is carried out while preventing heavy metals from being newly attached and diffused.

First, the semiconductor device 11 formed in the pre-process is diced into multiple pieces of semiconductor chips 21. Then, an adhesive is applied onto the support substrate 23 to form an adhesive layer 22. Then, the surface of the protection film of the semiconductor chip 21 is fixed onto the adhesive layer 22.

Then, the wiring layer 25 is connected to the semiconductor elements of the semiconductor chip 21 through the leads 24. Then, a resin is provided into the holes 22a and 23a to form the resin seal 27. Then, a thermal treatment is carried out at 150° C. for approximately 30 minutes so as to cure the adhesive layer 22 and the resin seal 27.

Then, the solder balls 26 are provided on the support substrate 23 to connect to the wiring layer 25. Then, a thermal treatment is carried out at 280° C. for approximately 30 seconds for connection of the solder balls 26. Thus, the BGA package 20 can be obtained.

As explained above, according to the first embodiment, the semiconductor substrate 1 is present from the film formation process to the element formation process. For this reason, heavy metals attached on the epitaxial semiconductor substrate 10 are trapped in the gettering layer included in the semiconductor substrate 1, thereby preventing the heavy metal contamination from affecting the semiconductor elements 3.

Additionally, a thermal treatment is carried out in the pre-process at a higher temperature for a longer time than in the post-process. Therefore, the trapping of heavy metals into the gettering layer dominates the releasing of the heavy metals. For this reason, the trapped heavy metals are prevented from being released.

Further, the post-process includes a thermal treatment carried out at a lower temperature for a shorter time than in the pre-process, and the semiconductor chip 21 includes no gettering layer with heavy metals trapped during the post-process. For this reason, the releasing of heavy metals in the semiconductor chip 21 does not occur, thereby preventing a degradation of the characteristics of the semiconductor elements, and preventing a decrease in the manufacturing yield.

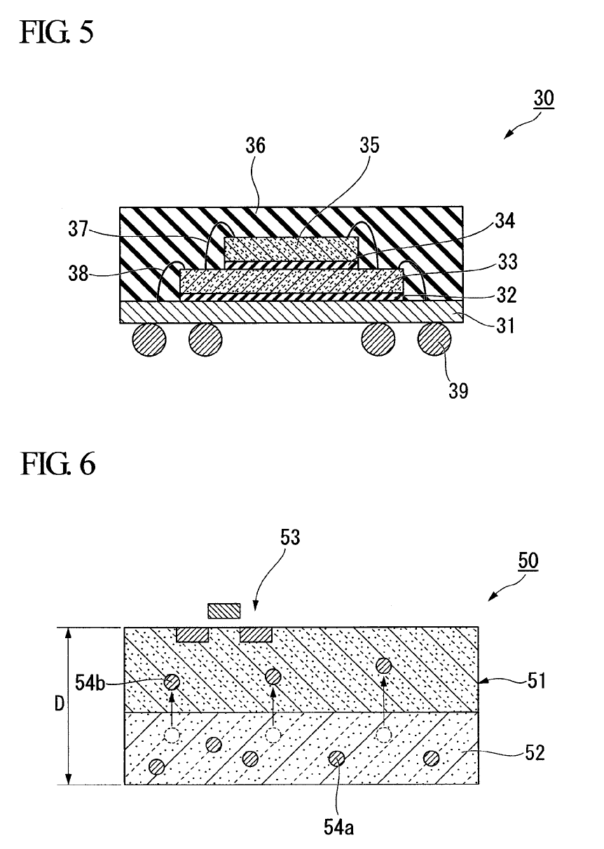

The present invention is not limited to the above embodiment. For example, a semiconductor device of the present invention may be an MCP (Multi-Chip Package) 30 as shown in FIG. 5. The MCP 30 includes a support substrate 31, a second semiconductor chip 33 fixed to the support substrate 31 through an adhesive layer 32, a first semiconductor chip 35 fixed to the second semiconductor chip 33 through an adhesive layer 34.

The support substrate 31 includes a wiring layer. The support substrate 31 is electrically connected to the second semiconductor chip 33 through bonding wires 38. The second semiconductor chip 33 is electrically connected to the first semiconductor chip 35 through bonding wires 37.

A resin seal 36 covers the support substrate 31, the first and second semiconductor chips 35 and 33, and the bonding wires 37 and 38. Multiple solder balls 39 are fixed to the support substrate 31. The solder balls 39 are connected to the wiring layer included in the support substrate 31. Thus, the solder balls 39 are electrically connected to the first and second semiconductor chips 35 and 33.

The first semiconductor chip 35 is obtained by dicing the semiconductor device 11 formed in the pre-process in a similar manner as the first embodiment. In other words, the first semiconductor chip 35 includes only the epitaxial layer that has no gettering layer and includes semiconductor elements.

The second semiconductor chip 33 may not necessarily be identical to the semiconductor chip obtained using the manufacturing method of the present invention as long as the second semiconductor chip 33 is an element (logic element or the like) that is hardly affected by a decrease in the yield due to the effect of heavy metal contamination in the assembly process.

In other words, the second semiconductor chip 33 may include a gettering layer as well as the epitaxial layer. Alternatively, a semiconductor chip, which is formed by forming semiconductor elements on a surface of a semiconductor substrate without forming an epitaxial layer from the beginning, may be used as the second semiconductor chip 33.

In other words, the present invention may be applied to chips whose characteristics are easily degraded due to the effect of heavy metal contamination. The kinds and the number of semiconductor chips to be stacked are not limited.

The MCP 30 can be formed by the following processes. First, the second semiconductor chip 33 is fixed to the support substrate 31 through the adhesive layer 32. Then, the first semiconductor chip 35 is fixed to the second semiconductor chip 33 through the adhesive layer 34.

Then, the second semiconductor chip 33 is connected to the support substrate 31 through the bonding wires 38. The first semiconductor chip 35 is connected to the second semiconductor chip 33 through the bonding wires 37. Then, these elements are sealed by the resin.

Then, a thermal treatment is carried out at 150° C. for approximately 30 minutes to cure the adhesive layers 32 and 34 and to cure the resin to form the resin seal 36. Then, the solder balls 39 are fixed to the support substrate 31 so as to connect to the wiring layer. In this case, a thermal treatment is carried out at 280° C. for approximately 30 seconds for connection of the solder balls 39 (assembly process). Thus, the MCP 30 can be obtained.

Although the film formation process is included in the method of manufacturing the semiconductor device 11, for example, an epitaxial semiconductor substrate, which includes a semiconductor substrate and an epitaxial layer on the semiconductor substrate, may be purchased without carrying out the film formation process, and then the element formation process and the removal process may be carried out.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

What is claimed is:

1. A method of manufacturing a semiconductor device, comprising:
forming an epitaxial layer on a semiconductor substrate;
forming a semiconductor element in the epitaxial layer; and
removing the semiconductor substrate from the epitaxial layer.

2. The method according to claim 1, wherein the epitaxial layer comprises a silicon layer having a thickness in the range of 10 to 100 μm.

3. The method according to claim 1, wherein removing the semiconductor substrate comprises grinding a rear surface of the semiconductor substrate.

4. A semiconductor device comprising:
a first semiconductor substrate comprising a semiconductor element, the first semiconductor substrate being free of a gettering layer.

5. The semiconductor device according to claim 4, wherein the first semiconductor substrate is made of mono-crystalline silicon.

6. The semiconductor device according to claim 4, comprising:
a second semiconductor substrate fixed to the first semiconductor substrate.

7. A method of manufacturing a semiconductor device, comprising:
forming a semiconductor substrate comprising a semiconductor base substrate and an epitaxial layer on the semiconductor base substrate, the semiconductor base substrate comprising a gettering layer;
forming a semiconductor element in the epitaxial layer, the gettering layer trapping heavy metal diffusing from the semiconductor substrate toward the epitaxial layer; and
removing the semiconductor base substrate from the epitaxial layer, the gettering layer being removed with the semiconductor base substrate.

8. The method according to claim 7, wherein forming the semiconductor substrate comprises forming the semiconductor base substrate by using a Czochralski method.

9. The method according to claim 7, wherein forming the semiconductor substrate comprises forming the gettering layer in the semiconductor base substrate by using oxygen precipitation in mono-crystalline silicon that forms the semiconductor base substrate.

10. The method according to claim 7, wherein forming the semiconductor substrate comprises forming the gettering layer in the semiconductor base substrate by physically damaging a rear surface of the semiconductor base substrate.

11. The method according to claim 7, wherein the epitaxial layer is formed by an epitaxial growth method in a hydrogen atmosphere.

12. The method according to claim 7, wherein removing the semiconductor base substrate comprises grinding a rear surface of the semiconductor base substrate.

13. The method according to claim 7, further comprising:
forming a protection film over the epitaxial layer after forming the semiconductor element, the protection film preventing heavy metal from diffusing toward the epitaxial layer through the protection film.

14. The semiconductor device according to claim 13, wherein the protection film comprises any one of silicon nitride and silicon oxynitride.

15. The method according to claim 7, further comprising:
polishing the epitaxial layer after removing the semiconductor substrate so that a final thickness of the semiconductor device is a predetermined value.

16. The method according to claim 7, further comprising:
adjusting a thickness of the epitaxial layer before forming the semiconductor element so that a final thickness of the semiconductor device is a predetermined value.

17. The method according to claim 7, further comprising:
assembling the epitaxial layer into a package after removing the semiconductor substrate.

18. The method according to claim 7, further comprising:
repeating a set of forming the semiconductor substrate, forming the semiconductor element, and removing the semiconductor base substrate to form a multi-chip-package structure that comprises a plurality of stacked epitaxial layers free of the gettering layer.

19. The method according to claim 7, further comprising:
stacking the epitaxial layer after removing the semiconductor base substrate over another semiconductor substrate including another gettering layer to form a multi-chip-package structure.

20. The method according to claim 7, wherein the epitaxial layer comprises a silicon layer having a thickness in the range of 10 to 100 μm.
